(19) United States
(12) Patent Application Publication
(10) Pub. No.: US 2023/0420915 A1
(43) Pub. Date: Dec. 28, 2023

(54) LIGHT-EMITTING DEVICE

(71) Applicant: Panasonic Intellectual Property Management Co., Ltd., Osaka (JP)

(72) Inventors: Yugo NOSE, KYOTO (JP); Manabu USUDA, HYOGO (JP); Masayuki SAWADA, KANAGAWA (JP); Shinzo KOYAMA, OSAKA (JP); Masato TAKEMOTO, OSAKA (JP)

(21) Appl. No.: 18/466,405

(22) Filed: Sep. 13, 2023

Related U.S. Application Data
(63) Continuation of application No. PCT/JP2022/001127, filed on Jan. 14, 2022.

(30) Foreign Application Priority Data
Mar. 18, 2021 (JP) 2021-044344

(51) Int. Cl. H01S 5/068; H01S 5/042

(52) U.S. Cl. CPC H01S 5/06808; H01S 5/0428

(57) ABSTRACT

The present disclosure allows a light-emitting device to detect a failure of a light-emitting circuit without affecting the waveform of a pulse current to be supplied to a light source element. The light-emitting device includes: a light-emitting circuit including a light source element; and a power supply configured to supply electric charges to the light-emitting circuit. The light-emitting circuit is provided between a power supply node and a ground node. The power supply is connected to the power supply node via a power supply line. A monitor detects an abnormal state of the light-emitting circuit by monitoring the voltage of the power supply line or the internal voltage of the power supply.

### CROSS-REFERENCE TO RELATED APPLICATIONS

This is a continuation of International Application No. PCT/JP2022/001127 filed on Jan. 14, 2022, which claims priority to Japanese Patent Application No. 2021-044344 filed on Mar. 18, 2021. The entire disclosures of these applications are incorporated by reference herein.

### BACKGROUND

The present disclosure relates to a light-emitting device capable of detecting a failure of a light-emitting circuit.

Japanese Unexamined Patent Publication No. 2020-149831 discloses a configuration for detecting a failure of a light emission driver configured to drive a light source element, in a light emission driving device. In this configuration, the light source element includes an anode to which a predetermined power supply voltage is applied from a power supply, and a cathode to which the light emission driver including a switch and a constant current source are connected. A pulse current flows through the light source element by turning the switch on and off. The failure detector detects a failure of the light emission driver, based on the voltage at the output terminal of the light emission driver.

### SUMMARY

In the configuration according to Japanese Unexamined Patent Publication No. 2020-149831, the failure detector is connected to an intermediate portion of the path of the pulse current to be supplied to the light source element. The presence of the failure detector affects the waveform of the pulse current, which may hinder normal light-emitting operation of the light source element.

The present disclosure was made in view of the problem. It is an objective of the present disclosure to provide a light-emitting device capable of detecting a failure of a light-emitting circuit without affecting the waveform of a pulse current to be supplied to a light source element.

A light-emitting device according to an aspect of the present disclosure includes: a light-emitting circuit provided between a power supply node and a ground node, the light-emitting circuit including a light source element; a power supply connected to the power supply node and configured to supply electric charges to the light-emitting circuit; and a monitor configured to monitor an electrical condition of the light-emitting circuit. The power supply is connected to the power supply node via a power supply line located outside the light-emitting circuit, and the monitor is configured to detect an abnormal state of the light-emitting circuit by monitoring a voltage of the power supply line or an internal voltage of the power supply.

According to the present disclosure, it is possible to detect, in a light-emitting device, a failure of a light-emitting circuit without affecting the waveform of a pulse current to be supplied to a light source element.

### BRIEF DESCRIPTION OF THE DRAWINGS

FIG. 1 is a circuit configuration of a light-emitting device according to an embodiment.

FIGS. 2A and 2B show examples of a pulse current flowing through a light source element and an anode voltage and a cathode voltage of the light source element. FIG. 2A shows the embodiment, while FIG. 2B shows a comparative example.

FIG. 3 is another circuit configuration of the light-emitting device according to the embodiment.

FIG. 4 shows a specific example configuration of the light-emitting device in FIG. 1.

FIG. 5 shows how to detect a “high-fixed” state.

FIG. 6 shows how to detect an overvoltage.

FIG. 7 shows how to detect an open fault.

FIG. 8 is a flowchart showing an example operation of failure detection.

FIG. 9 is a circuit configuration of a light-emitting device according to a variation.

### DETAILED DESCRIPTION

### Summary

A light-emitting device according to an aspect of the present disclosure includes: a light-emitting circuit provided between a power supply node and a ground node, the light-emitting circuit including a light source element; a power supply connected to the power supply node and configured to supply electric charges to the light-emitting circuit; and a monitor configured to monitor an electrical condition of the light-emitting circuit, the power supply being connected to the power supply node via a power supply line located outside the light-emitting circuit, the monitor being configured to detect an abnormal state of the light-emitting circuit by monitoring a voltage of the power supply line or an internal voltage of the power supply.

According to this configuration, the light-emitting device includes: the light-emitting circuit including the light source element; and the power supply configured to supply the electric charges to the light-emitting circuit. The light-emitting circuit is provided between the power supply node and the ground node. The power supply is connected to the power supply node via the power supply line located outside the light-emitting circuit. The light-emitting device includes the monitor configured to detect the abnormal state of the light-emitting circuit by monitoring the voltage of the power supply line or the internal voltage of the power supply. According to this configuration, the monitor monitors the voltage at the node outside the light-emitting circuit; therefore, the waveform of the pulse current causing the light source element to emit light is not affected. It is therefore possible to detect a failure of the light-emitting circuit without affecting the waveform of the pulse current to be supplied to the light source element.

The light-emitting circuit may include: a switch configured to switch between a conductive state and a non-conductive state in accordance with a signal supplied from a signal generator; and a charge and discharge circuit capable of storing electric charges, and the light source element and the switch may be connected in series between the power supply node and the ground node, and the charge and discharge circuit may be connected in parallel with the light source element and the switch, between the power supply node and the ground node.

Accordingly, in the light-emitting circuit, when the switch is in the conductive state, the electric charges stored in the charge and discharge circuit are supplied to the light source element to cause the light source element to emit light; and when the switch is in the non-conductive state, the light source element emits no light, and the electric charges supplied from the power supply are stored in the charge and discharge circuit. Further, the monitor is not connected inside the loop path where the pulse current causing the light source element to emit light flows, and monitors the voltage at the node located outside the loop path. Thus, the waveform of the pulse current is not affected. It is therefore possible to detect a failure of the light-emitting circuit without affecting the waveform of the pulse current to be supplied to the light source element.

The monitor may include: a voltage divider resistor connected to the power supply line; and a comparator configured to compare a voltage divided by the voltage divider resistor with a predetermined threshold voltage.

Accordingly, the monitor can detect the abnormal state of the light-emitting circuit by monitoring the voltage of the power supply line.

The power supply may include a charge time constant adjuster including a resistor for adjusting a charge time constant, and the monitor may include: first and second voltage divider resistors respectively connected to both ends of the resistor; a differential amplifier configured to amplify a difference between voltages divided by the first and second voltage divider resistors; and a comparator configured to compare an output of the differential amplifier with a predetermined threshold voltage.

Accordingly, the monitor can detect the abnormal state of the light-emitting circuit by monitoring the internal voltage of the power supply.

A light-emitting device according to another aspect of the present disclosure includes: a light-emitting circuit provided between a power supply node and a ground node, the light-emitting circuit including a light source element; a power supply connected to the power supply node and configured to supply electric charges to the light-emitting circuit; and a monitor configured to monitor an electrical condition of the light-emitting circuit, the power supply being connected to the power supply node via a power supply line located outside the light-emitting circuit, the light-emitting circuit including: a switch configured to switch between a conductive state and a non-conductive state in accordance with a signal supplied from a signal generator; and a charge and discharge circuit configured to store electric charges, the light source element and the switch being connected in series between the power supply node and the ground node, and the charge and discharge circuit being connected to be in parallel with the light source element and the switch, between the power supply node and the ground node, the monitor being configured to detect an abnormal state of a current flowing through the charge and discharge circuit.

According to this configuration, the light-emitting device includes: the light-emitting circuit including the light source element; and the power supply configured to supply the electric charges to the light-emitting circuit. The light-emitting circuit is provided between the power supply node and the ground node. The power supply is connected to the power supply node via the power supply line located outside the light-emitting circuit. In the light-emitting circuit, when the switch is in the conductive state, the electric charges stored in the charge and discharge circuit are supplied to the light source element to cause the light source element to emit light; and when the switch is in the non-conductive state, the light source element emits no light, and the electric charges supplied from the power supply are stored in the charge and discharge circuit. The light-emitting device includes the monitor configured to detect the abnormal state of the current flowing through the charge and discharge circuit. It is therefore possible to detect a failure of the light-emitting circuit without affecting the waveform of the pulse current to be supplied to the light source element.

The monitor may detect, as the abnormal state, at least one of a state where the switch is fixed to a conductive state allowing the current to keep flowing through the light source element, a state where an overvoltage is applied to the light source element, or a state where the switch is fixed to be a non-conductive state not allowing the current to flow through the light source element.

Now, an embodiment will be described with reference to the drawings. However, unnecessarily detailed description may be omitted. For example, detailed description of matters that are already well known or repeated description of substantially the same configurations may be omitted. This is to reduce unnecessary redundancy of the following description and facilitate the understanding by those skilled in the art.

The accompanying drawings and the following description are provided for sufficient understanding of the present disclosure by those skilled in the art, and are not intended to limit the subject matter of the claims.

### Embodiment

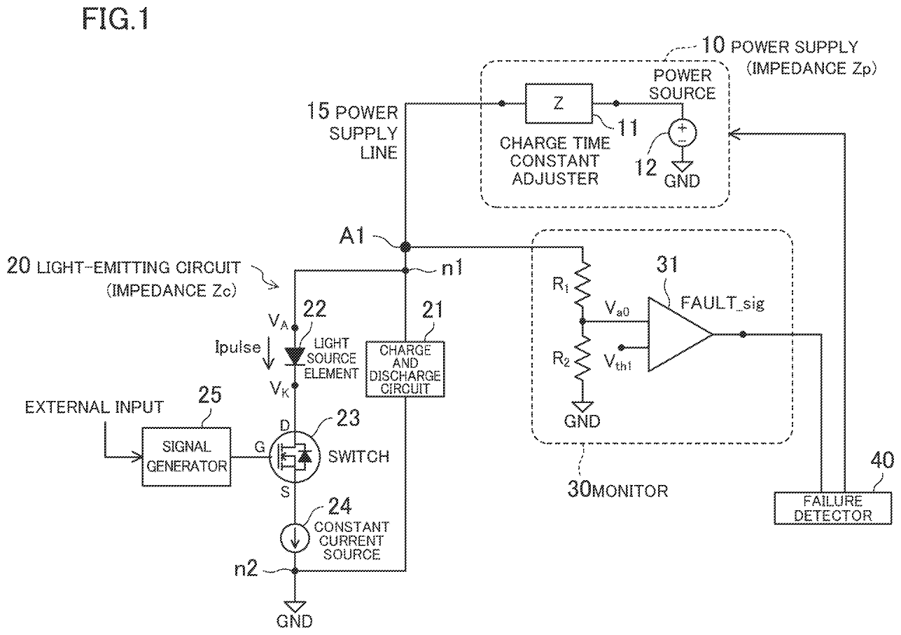

FIG. 1 is a circuit configuration of a light-emitting device according to an embodiment. The light-emitting device of FIG. 1 is used, for example, for a system that obtains information on the distance to an object by the time-of-flight (TOF) method. The light-emitting device of FIG. 1 includes a power supply 10, a light-emitting circuit 20, a signal generator 25, a monitor 30, and a failure detector 40.

The light-emitting circuit 20 includes a light source element 22, which is a laser diode, and is provided between a power supply node n1 and a ground node n2. The light source element 22 is connected in series with a switch 23 and a constant current source 24 between the power supply node n1 and the ground node n2. The light source element 22 includes an anode connected to the power supply node n1 and a cathode connected to the switch 23. The switch 23 is, for example, a field-effect transistor (FET) with a gate supplied with a signal from the signal generator 25. The switch 23 is turned on (i.e., a conductive state) and off (i.e., a non-conductive state) by the signal supplied from the signal generator 25.

A charge and discharge circuit 21 is connected in parallel with the light source element 22 and the switch 23, between the power supply node n1 and the ground node n2. The charge and discharge circuit 21 can store electric charges and is composed of a capacitor, for example.

The arrangement of the constant current source 24 makes it possible to adjust the maximum amount of current flowing through the light-emitting circuit 20.

The power supply 10 is connected to the power supply node n1 via a power supply line and supplies the electric charges to the light-emitting circuit 20. The electric charges supplied from the power supply 10 are stored in the charge and discharge circuit 21. The power supply includes: a charge time constant adjuster 11 and a power source 12. The charge time constant adjuster 11 adjusts the time constant for charging, that is, for supplying the electric charges.

When the switch 23 is on, the electric charges stored in the charge and discharge circuit 21 are supplied to the light source element 22, causing the light source element 22 to emit light. On the other hand, when the switch 23 is off, no current flows to the light source element 22, which thus emits no light, and the electric charges supplied from the power supply 10 are stored in the charge and discharge circuit 21. The light-emitting circuit 20 forms a loop path where a pulse current flows to cause the light source element 22 to emit light.

The monitor 30 monitors the electrical condition of the light-emitting circuit 20. The monitor 30 is connected to the power supply line 15 (namely at a monitoring node A1) and detects an abnormal state of the light-emitting circuit 20 by monitoring the voltage of the power supply line 15. The monitor 30 includes: voltage divider resistors R1 and R2 connected to the power supply line 15; and a comparator 31 configured to compare a voltage Vao divided by the voltage divider resistors R1 and R2 with a predetermined threshold voltage Vth1. The output of the comparator 31 is sent to the failure detector 40.

Here, the voltage at the monitoring node A1 is equal to the anode voltage VA of the light source element 22. It is thus possible to monitor the electrical condition of the light-emitting circuit 20 by monitoring the voltage at the monitoring node A1. In addition, the relationship between Zc and Zp, where Zc is the impedance of the light-emitting circuit 20 and Zp is the impedance of the power supply 10, is as follows:

Zc<<Zp

The monitoring node A1 is located outside the loop path where the pulse current flows in the light-emitting circuit 20. Thus, monitoring of the voltage at the monitoring node A1 by the monitor 30 does not affect the waveform of the pulse current.

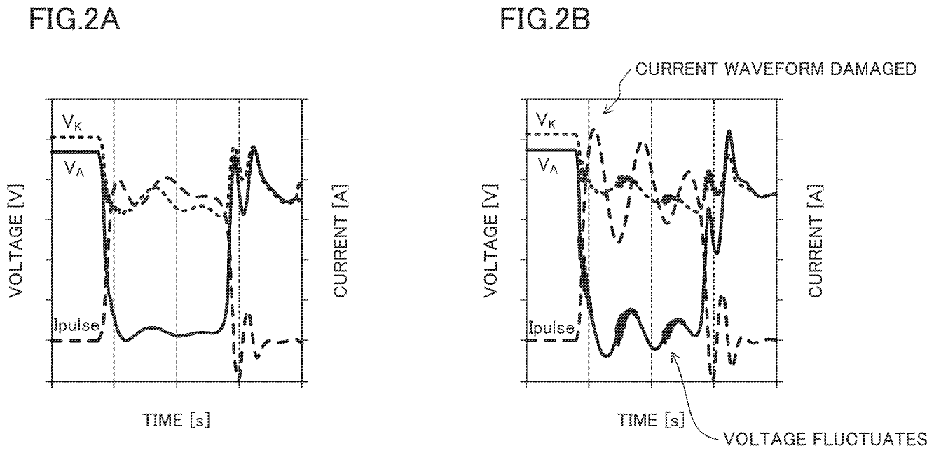

FIG. 2 shows graphs each showing an example of a pulse current Ipulse flowing through the light source element 22, and an anode voltage VA and a cathode voltage VK of the light source element 22. FIG. 2A shows a case of the configuration of FIG. 1, that is, a case in which the monitor 30 monitors the voltage at the monitoring node A1. FIG. 2B shows, as a comparative example, a case in which the monitor 30 monitors the voltage at a node between the light source element 22 and the switch 23 in the light-emitting circuit 20.

As can be seen from FIG. 2B, in the case in which the monitor 30 is connected to the node in the loop path of the light-emitting circuit 20, the waveform of the pulse current Ipulse flowing through the light source element 22 is damaged, and the anode voltage VA of the light source element 22 fluctuates and consumes extra power. By contrast, according to this embodiment, the monitor 30 monitors the voltage at the monitoring node A located outside the loop path of the light-emitting circuit 20; therefore, the waveform of the pulse current Ipulse flowing through the light source element 22 is not affected as shown in FIG. 2A.

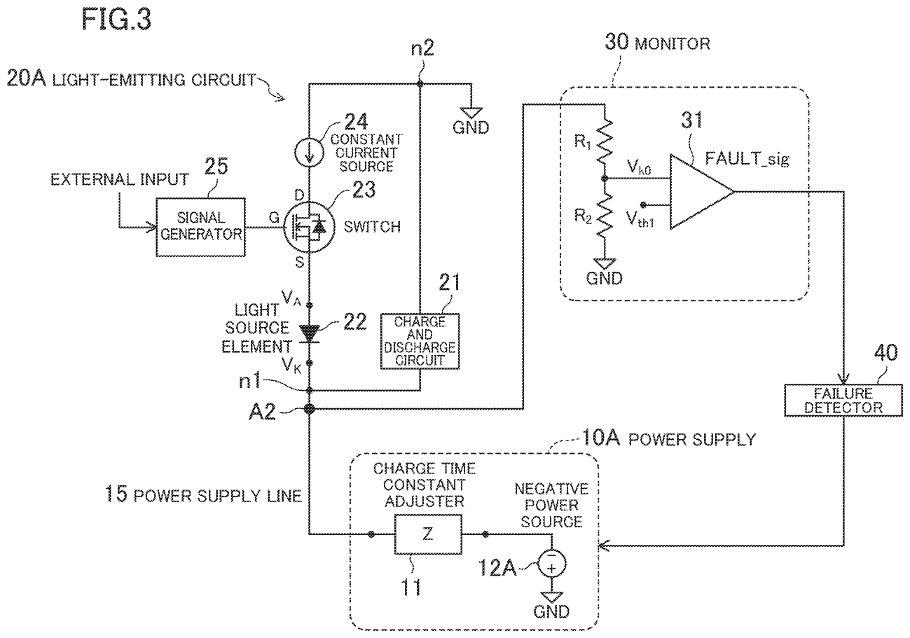

FIG. 3 is another circuit configuration of the light-emitting device according to the embodiment. In the light-emitting device shown in FIG. 3, a light-emitting circuit 20A is supplied with negative power from a power supply 10A.

In the light-emitting circuit 20A, a light source element 22 is connected in series with a switch 23 and a constant current source 24 between a power supply node n1 and a ground node n2. The light source element 22 includes a cathode connected to the power supply node n1 and an anode connected to the switch 23. A charge and discharge circuit 21 is connected in parallel with the light source element 22 and the switch 23, between the power supply node n1 and the ground node n2.

The power supply 10A is connected to the power supply node n1 via a power supply line 15 and supplies electric charges to the light-emitting circuit 20A. The electric charges supplied from the power supply 10A are stored in the charge and discharge circuit 21. The power supply 10A includes a charge time constant adjuster 11 and a negative power source 12A.

When the switch 23 is on, the electric charges stored in the charge and discharge circuit 21 are supplied to the light source element 22, causing the light source element 22 to emit light. On the other hand, when the switch 23 is off, no current flows to the light source element 22, which thus emits no light, and the electric charges supplied from the power supply 10 are stored in the charge and discharge circuit 21. This operation is the same or similar to that of the configuration shown in FIG. 1. The light-emitting circuit 20A, too, forms a loop path where a pulse current flows to cause the light source element 22 to emit light.

The monitor 30 is connected to the power supply line 15 (namely at a monitoring node A2) and detects an abnormal state of the light-emitting circuit 20A by monitoring the voltage of the power supply line 15.

The circuit configuration in FIG. 3 can provide effects that are the same or similar to those of the circuit configuration in FIG. 1. That is, the voltage at the monitoring node A2 is equal to the cathode voltage VK of the light source element 22. It is thus possible to monitor the electrical condition of the light-emitting circuit 20 by monitoring the voltage at the monitoring node A2. In addition, the monitoring node A2 is located outside the loop path where the pulse current flows in the light-emitting circuit 20A. Thus, monitoring of the voltage at the monitoring node A2 by the monitor 30 does not affect the waveform of the pulse current.

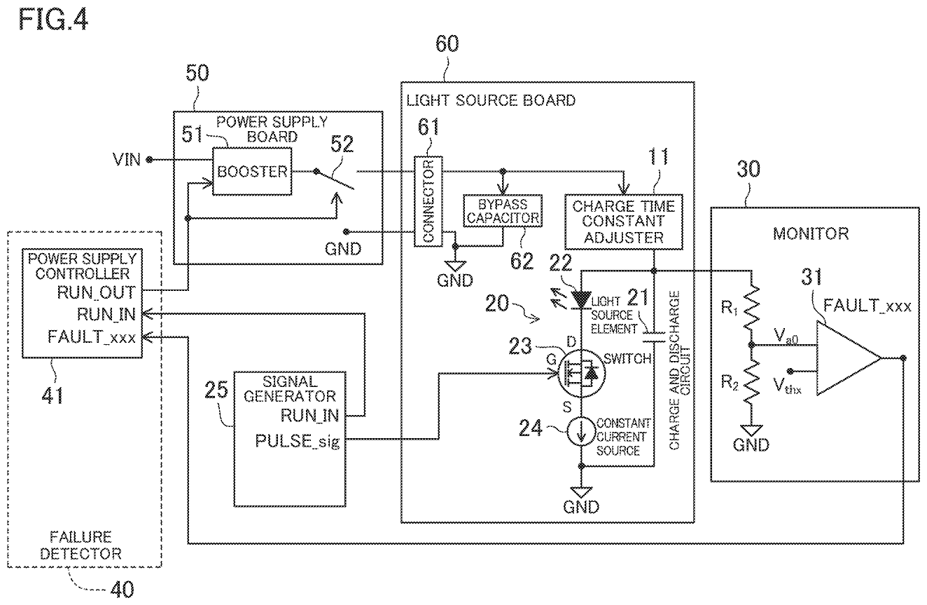

FIG. 4 shows a specific example configuration of the light-emitting device in FIG. 1. The configuration of FIG. 4 includes a power supply board 50 and a light source board 60. The light-emitting circuit 20 shown in FIG. 1 is placed on the light source board 60. The power supply board 50 and the light source board 60 are connected via a connector 61. Arranged on the power supply board 50 are: a booster 51 that boosts an input voltage VIN; and a switch 52 for allowing and not allowing the transmission of the output of the booster 51 to the light source board 60. In addition to the light-emitting circuit 20, the charge time constant adjuster 11 and a bypass capacitor 62 are arranged on the light source board 60. The configuration including: the power supply board 50; and the charge time constant adjuster 11 and the bypass capacitor 62 which are arranged on the light source board 60 corresponds to the power supply 10 shown in FIG. 1. Further, the failure detector 40 includes a power supply controller 41 configured to control the booster 51 and the switch 52 on the power supply board 50 upon receipt of the output from the monitor 30. The power supply controller 41 is implemented by a microprocessor, for example.

A method of detecting an abnormal state of the light-emitting circuit 20 will be described with reference to the configuration of FIG. 4. In this embodiment, a “high-fixed” state, an overvoltage, and an open fault are detected as the abnormal state of the light-emitting circuit 20. Here, the “high-fixed” state is the state where the gate voltage of the switch 23 is fixed to a high level and the switch 23 is fixed to the on state. In this case, the switch 23 is fixed to the conductive state, allowing the current to keep flowing through the light source element 22. The switch 23 may be fixed to the conductive state due to a failure. The overvoltage is the state where an excessive voltage higher than a normal voltage is applied to the light source element 22. The open fault is the state where the switch 23 is not turned on but fixed to the off state. In this case, the switch 23 is fixed to the non-conductive state, not allowing the current to flow through the light source element 22.

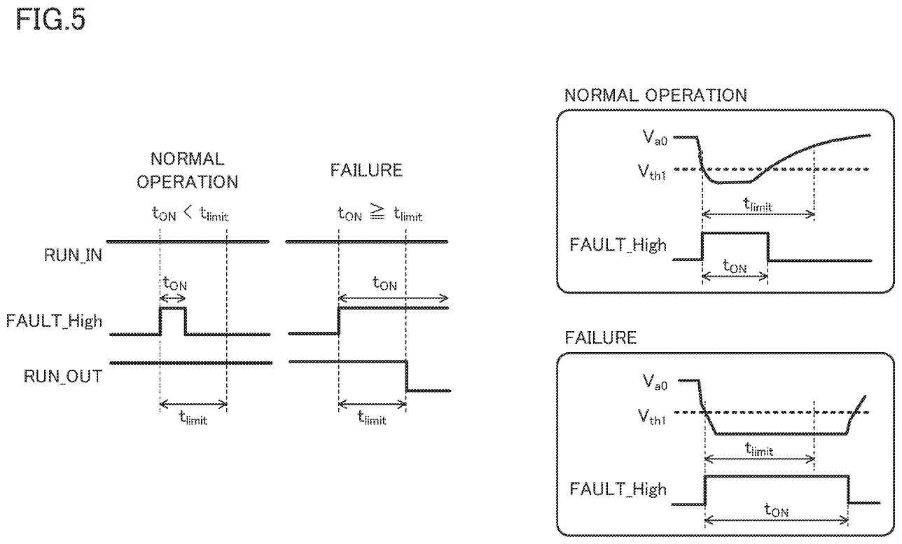

FIG. 5 shows how to detect a “high-fixed” state. In this case, the comparator 31 of the monitor 30 outputs a signal FAULT_High using the threshold voltage Vth1. The comparator 31 sets the signal FAULT_High to a high level when Vao is lower than Vth1. The power supply controller 41 compares the period tON, in which the signal FAULT_High is the high level, with the upper limit time tlimit. If the period tON is longer than the upper limit time tlimit, the power supply controller 41 determines that the light-emitting circuit 20 is in the “high-fixed” state, causes a signal RUN_OUT to be a low level, and sends the signal RUN_OUT to the power supply board 50. The booster 51 stops the boosting operation, and the switch 52 is turned off. The power supply to the light source board 60 stops accordingly.

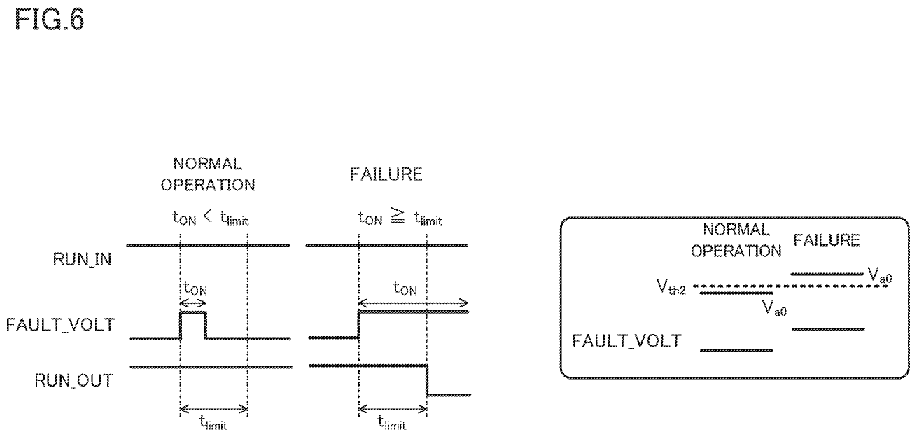

FIG. 6 shows how to detect an overvoltage. In this case, the comparator 31 of the monitor 30 outputs a signal FAULT_VOLT using a threshold voltage Vth2. The comparator 31 sets the signal FAULT_VOLT to be a high level when Vao is higher than Vth2. The power supply controller 41 compares the period tON, in which the signal FAULT_VOLT is the high level, with the upper limit time tlimit. If the period tON is longer than the upper limit time tlimit, the power supply controller 41 determines that the light-emitting circuit 20 is in the overvoltage, causes the signal RUN_OUT to be a low level, and sends the signal RUN_OUT to the power supply board 50. The booster 51 stops the boosting operation, and the switch 52 is turned off. The power supply to the light source board 60 stops accordingly.

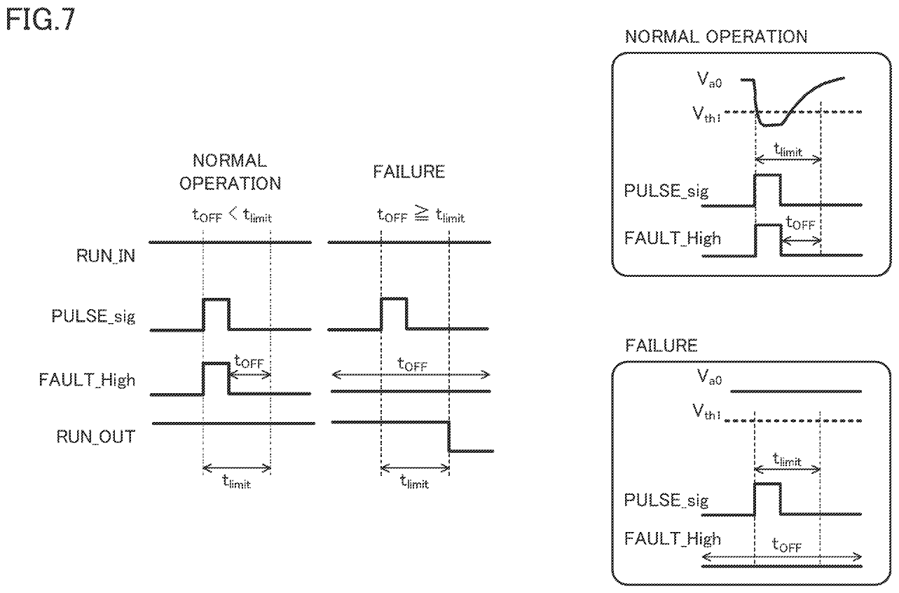

FIG. 7 shows how to detect an open fault. In this case, the comparator 31 of the monitor outputs a signal FAULT_High using the threshold voltage Vth1. The comparator 31 sets the signal FAULT_High to a high level when Vao is lower than Vth1. When the period in which although the signal PULSE_sig to be supplied to the switch 23 becomes high level, the signal FAULT_High does not become high level is longer than the upper limit time tlimit, the power supply controller 41 determines that the open fault has occurred, causes the signal RUN_OUT to be a low level, and sends the signal to the power supply board 50. The booster 51 stops the boosting operation, and the switch 52 is turned off. The power supply to the light source board stops accordingly.

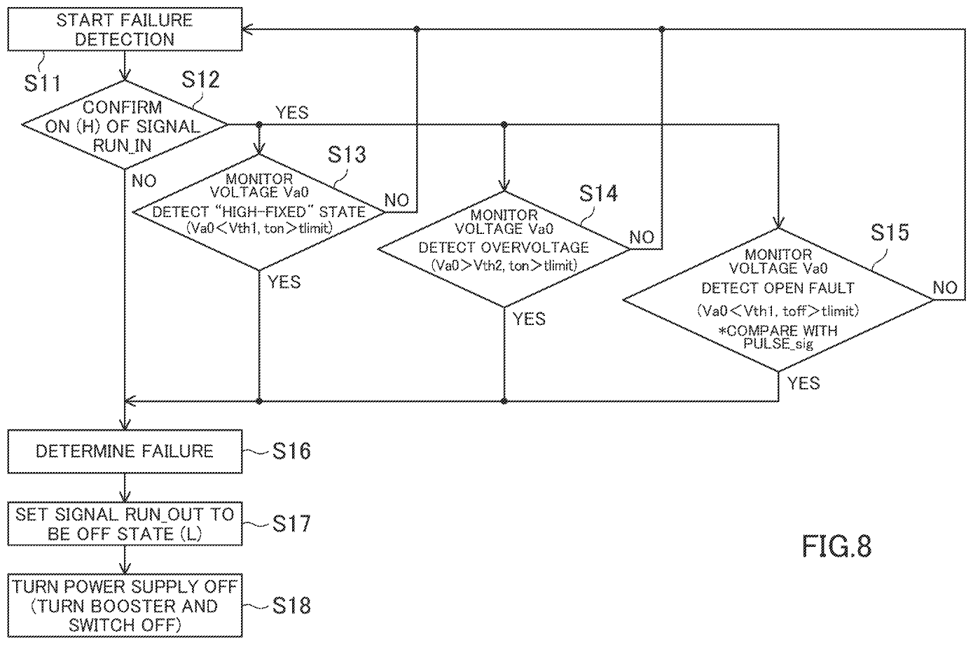

FIG. 8 is a flowchart showing an example of a failure detection operation in the example configuration in FIG. 4. In this example operation, the monitor 30 includes comparators 31 separately for a “high-fixed” state, an overvoltage, and an open fault.

When the failure detection starts (S11), the power supply controller 41 confirms that a signal RUN_IN output from the signal generator 25 is the on state (i.e., high level) (S12). When the on state (i.e., high level) of the signal RUN_IN is confirmed, the monitor 30 and the power supply controller 41 detect a “high-fixed” state, an overvoltage, and an open fault in the manners described above (S13, S14, and S15). If none of a “high-fixed” state, an overvoltage, or an open fault is detected, the operation ends. On the other hand, when at least one of a “high-fixed” state, an overvoltage, or an open fault is detected, the power supply controller 41 determines that the light-emitting circuit 20 has a failure (S16) and sets the signal RUN_OUT to be the off state (i.e., low level) (S17). The power supply to the power supply board 50 stops (S18) accordingly. Also when it cannot be confirmed that the signal RUN_IN is the on state (i.e., high level) in S12, the power supply controller 41 determines that the light-emitting circuit has a failure (S16) and sets the signal RUN_OUT to be the off state (i.e., low level) (S17).

(Variation)

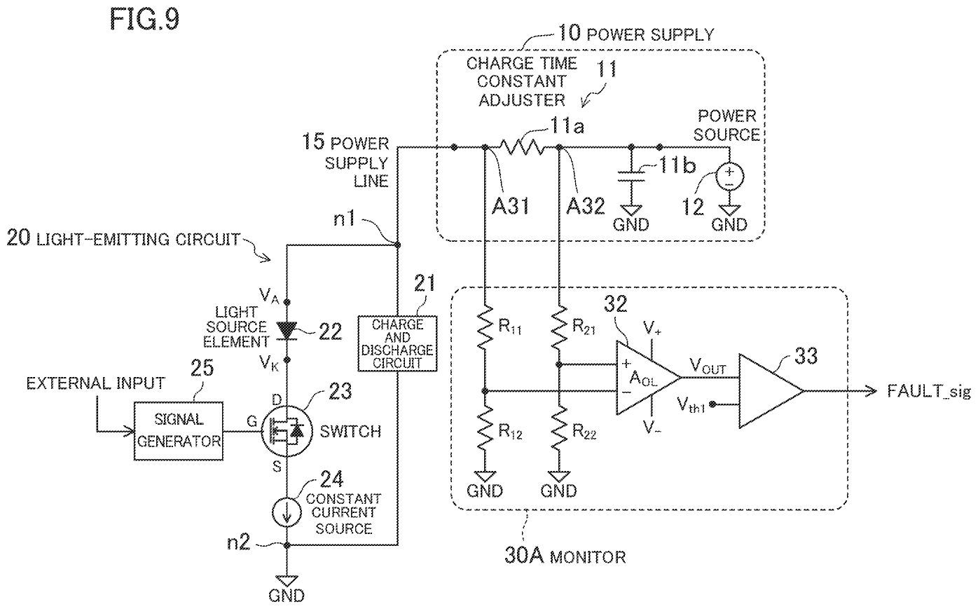

FIG. 9 is a circuit configuration of a light-emitting device according to a variation. In the circuit configuration of FIG. 9, a monitor 30A detects an abnormal state of the light-emitting circuit 20 by monitoring not the voltage of the power supply line 15 but the internal voltage of the power supply 10.

In FIG. 9, the charge time constant adjuster 11 included in the power supply 10 includes a resistor 11a and a capacitor 11b. The monitor 30A monitors the voltages at both ends of the resistor 11a included in the charge time constant adjuster 11. The monitor 30A includes first voltage divider resistors R11 and R12, second voltage divider resistors R21 and R22, a differential amplifier 32, and a comparator 33. The first voltage divider resistors R11 and R12 are connected to one end (i.e., a monitoring node A31) of the resistor 11a. The second voltage divider resistors R21 and R22 are connected to the other end (i.e., a monitoring node A32) of the resistor 11a. The differential amplifier 32 amplifies the difference between the voltage divided by the first voltage divider resistors R11 and R12 and the voltage divided by the second voltage divider resistors R21 and R22. The comparator 33 compares an output VOUT of the differential amplifier 32 with the predetermined threshold voltage Vth1.

Here, the potential difference between the monitoring node A31 and the monitoring node A32 serves as a signal following a current component flowing through the resistor 11a. It is thus possible to monitor the electrical condition of the light-emitting circuit 20 by monitoring the potential difference between the monitoring nodes A31 and A32. In addition, the monitoring nodes A31 and A32 are located inside the power supply 10 and outside the loop path where the pulse current flows in the light-emitting circuit 20. Thus, monitoring of the voltages at the monitoring nodes A31 and A32 by the monitor 30A does not affect the waveform of the pulse current. Further, a noise component can be removed using the difference of the voltages between both ends of the resistor 11a, thereby making it possible to reduce the influence of noise.

The light-emitting device according to the present disclosure can detect a failure of a light-emitting circuit without affecting the waveform of a pulse current to be supplied to a light source element, and is thus useful, for example, in improving the safety of the light-emitting device.

What is claimed is:

1. A light-emitting device comprising:
a light-emitting circuit provided between a power supply node and a ground node, the light-emitting circuit including a light source element;
a power supply connected to the power supply node and configured to supply electric charges to the light-emitting circuit; and
a monitor configured to monitor an electrical condition of the light-emitting circuit,
the power supply being connected to the power supply node via a power supply line located outside the light-emitting circuit,
the monitor being configured to detect an abnormal state of the light-emitting circuit by monitoring a voltage of the power supply line or an internal voltage of the power supply.

2. The light-emitting device of claim 1, wherein
the light-emitting circuit includes:
a switch configured to switch between a conductive state and a non-conductive state in accordance with a signal supplied from a signal generator; and
a charge and discharge circuit capable of storing electric charges, and
the light source element and the switch are connected in series between the power supply node and the ground node, and the charge and discharge circuit is connected in parallel with the light source element and the switch, between the power supply node and the ground node.

3. The light-emitting device of claim 1, wherein
the monitor includes:
a voltage divider resistor connected to the power supply line; and
a comparator configured to compare a voltage divided by the voltage divider resistor with a predetermined threshold voltage.

4. The light-emitting device of claim 1, wherein
the power supply includes a charge time constant adjuster including a resistor for adjusting a charge time constant, and
the monitor includes:
first and second voltage divider resistors respectively connected to both ends of the resistor;
a differential amplifier configured to amplify a difference between voltages divided by the first and second voltage divider resistors; and
a comparator configured to compare an output of the differential amplifier with a predetermined threshold voltage.

5. A light-emitting device comprising:
a light-emitting circuit provided between a power supply node and a ground node, the light-emitting circuit including a light source element;
a power supply connected to the power supply node and configured to supply electric charges to the light-emitting circuit; and
a monitor configured to monitor an electrical condition of the light-emitting circuit,
the power supply being connected to the power supply node via a power supply line located outside the light-emitting circuit,
the light-emitting circuit including:
a switch configured to switch between a conductive state and a non-conductive state in accordance with a signal supplied from a signal generator; and
a charge and discharge circuit configured to store electric charges,
the light source element and the switch being connected in series between the power supply node and the ground node, and the charge and discharge circuit being connected to be in parallel with the light source element and the switch, between the power supply node and the ground node,
the monitor being configured to detect an abnormal state of a current flowing through the charge and discharge circuit.

6. The light-emitting device of claim 5, wherein
the monitor detects, as the abnormal state, at least one of a state where the switch is fixed to a conductive state allowing the current to keep flowing through the light source element, a state where an overvoltage is applied to the light source element, or a state where the switch is fixed to be a non-conductive state not allowing the current to flow through the light source element.

7. The light-emitting device of claim 2, wherein
the monitor includes:
a voltage divider resistor connected to the power supply line; and
a comparator configured to compare a voltage divided by the voltage divider resistor with a predetermined threshold voltage.

8. The light-emitting device of claim 2, wherein
the power supply includes a charge time constant adjuster including a resistor for adjusting a charge time constant, and
the monitor includes:
first and second voltage divider resistors, each connected to one end of the resistor;
a differential amplifier configured to amplify a difference between voltages divided by the first and second voltage divider resistors; and
a comparator configured to compare an output of the differential amplifier with a predetermined threshold voltage.
